(19) United States
(12) Patent Application Publication
(10) Pub. No.: US 2022/0046806 A1
(43) Pub. Date: Feb. 10, 2022

(54) METHOD FOR MANUFACTURING PRINTED WIRING BOARD

(71) Applicant: IBIDEN CO., LTD., Ogaki (JP)

(72) Inventors: Satoru KAWAI, Ogaki (JP); Saori KITAHARA, Ogaki (JP); Akifumi SHIKANO, Ogaki (JP); Miki TAKAKI, Ogaki (JP)

(73) Assignee: IBIDEN CO., LTD., Ogaki (JP)

(21) Appl. No.: 17/388,653

(22) Filed: Jul. 29, 2021

(30) Foreign Application Priority Data
Aug. 7, 2020 (JP) 2020-134775

(51) Int. Cl. H05K 3/38; H05K 3/10; C25D 5/56; C25D 5/02; C23C 18/42; C23F 17/00

(52) U.S. Cl. CPC H05K 3/381; H05K 3/108; C25D 5/56; C25D 5/022; H05K 2203/095; C23F 17/00; H05K 2203/0716; H05K 2203/072; H05K 2203/0723; C23C 18/42

(57) ABSTRACT

A method for manufacturing a printed wiring board includes forming the outermost conductor layer on the outermost resin insulating layer, forming a solder resist layer on the outermost resin insulating layer such that the solder resist layer covers the outermost conductor layer formed on the outermost resin insulating layer, irradiating plasma upon an exposed surface of the solder resist layer formed on the outermost conductor layer, forming a catalyst on the exposed surface of the solder resist layer formed on the outermost conductor layer, and forming an electroless plating layer on the exposed surface of the solder resist layer via the catalyst formed on the exposed surface of the solder resist layer such that the electroless plating layer has a film thickness in a range of 0.22 μm to 0.38 μm.

### CROSS-REFERENCE TO RELATED APPLICATIONS

The present application is based upon and claims the benefit of priority to Japanese Patent Application No. 2020-134775, filed Aug. 7, 2020, the entire contents of which are incorporated herein by reference.

### BACKGROUND OF THE INVENTION

### Field of the Invention

The present invention relates to forming an electroless plating coating film on a solder resist layer.

### Description of Background Art

Japanese Patent No. 5579160 describes that a palladium catalyst is formed in order to deposit electroless plating on a resin insulating layer. An adsorption amount of the palladium catalyst in Japanese Patent No. 5579160 is 5-1000 mg/m², and a film thickness of the electroless plating is 0.2-2.0 μm. The entire contents of this publication are incorporated herein by reference.

### SUMMARY OF THE INVENTION

According to one aspect of the present invention, a method for manufacturing a printed wiring board includes forming the outermost conductor layer on the outermost resin insulating layer, forming a solder resist layer on the outermost resin insulating layer such that the solder resist layer covers the outermost conductor layer formed on the outermost resin insulating layer, irradiating plasma upon an exposed surface of the solder resist layer formed on the outermost conductor layer, forming a catalyst on the exposed surface of the solder resist layer formed on the outermost conductor layer, and forming an electroless plating layer on the exposed surface of the solder resist layer via the catalyst formed on the exposed surface of the solder resist layer such that the electroless plating layer has a film thickness in a range of 0.22 μm to 0.38 μm.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIGS. 1A-1E are manufacturing process diagrams of a printed wiring board according to an embodiment of the present invention;

FIGS. 2A-2E are the manufacturing process diagrams of a printed wiring board of the embodiment;

FIGS. 3A-3D are the manufacturing process diagrams of a printed wiring board of the embodiment;

FIG. 4 is a planar photograph of an electroless plating layer of Example 1;

FIG. 5 is a planar photograph of an electroless plating layer of Comparative Example 1; and

FIGS. 6A-6C are schematic diagrams of palladium catalyst application.

### DETAILED DESCRIPTION OF THE EMBODIMENTS

Embodiments will now be described with reference to the accompanying drawings, wherein like reference numerals designate corresponding or identical elements throughout the various drawings.

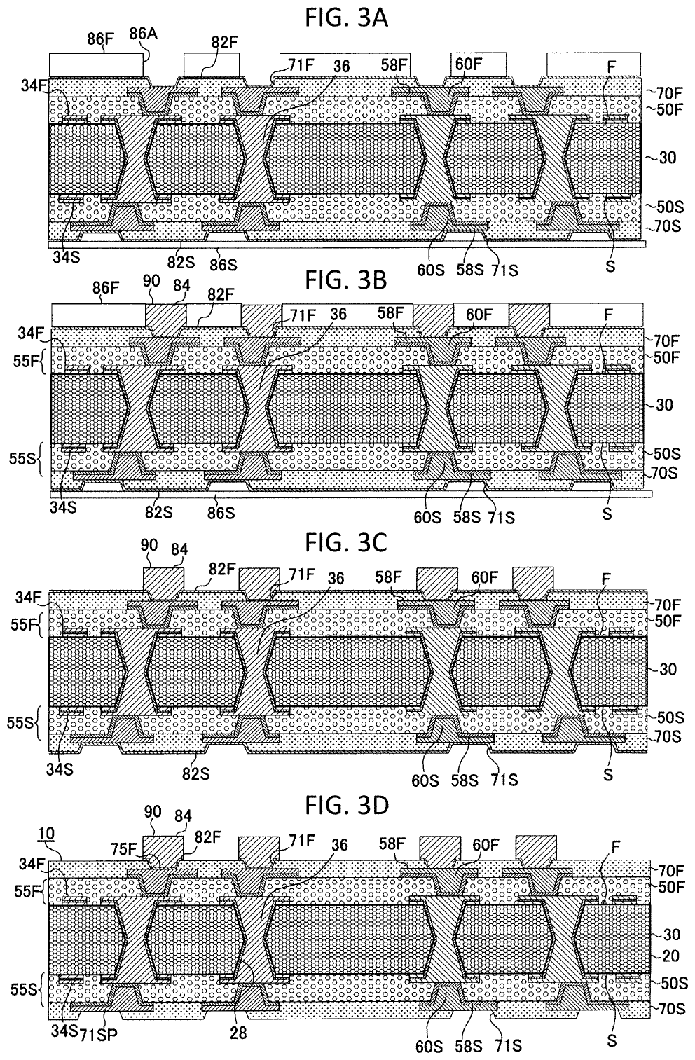

A printed wiring board 10 according to an embodiment of the present invention is illustrated in FIG. 3D. In the printed wiring board 10, metal posts 90 are formed on an outermost conductor layer (58F). The metal posts 90 are formed of an electroless plating layer (82F) and an electrolytic plating film 84 on the electroless plating layer (82F).

The printed wiring board 10 of the embodiment may be a printed wiring board having a core substrate, or may be a coreless substrate. A printed wiring board having a core substrate and a method for manufacturing the printed wiring board are described, for example, in JP2007227512A. A coreless substrate and a manufacturing method thereof are described, for example, in JP2005236244A.

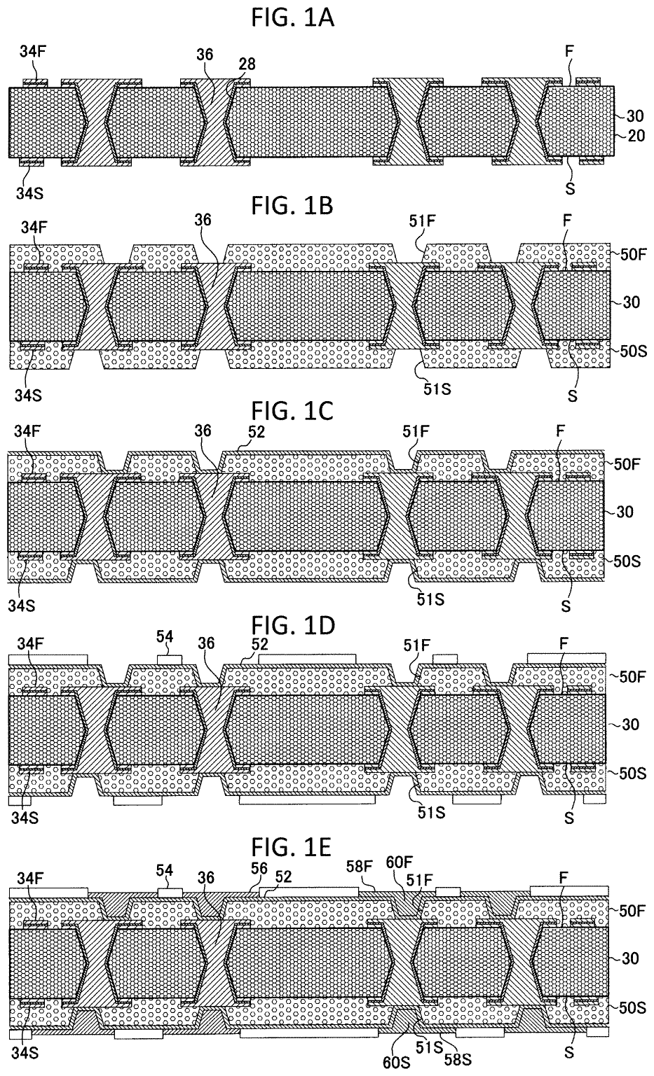

As illustrated in FIGS. 1A and 3D, the printed wiring board 10 of the embodiment has a core substrate 30. The core substrate 30 includes: an insulating substrate 20 having a first surface (F) and a second surface (S) on an opposite side with respect to the first surface (F); a first conductor layer (34F) formed on the first surface (F) of the insulating substrate 20; and a second conductor layer (34S) formed on the second surface of the insulating substrate 20. The core substrate 30 further includes through holes 28 for through-hole conductors formed in the insulating substrate 20. The through holes 28 are filled with a plating film to form through-hole conductors 36. The through-hole conductors 36 connect the first conductor layer (34F) and the second conductor layer (34S) to each other. A first surface (F) of the core substrate 30 and the first surface (F) of the insulating substrate 20 are the same surface, and a second surface (S) of the core substrate 30 and the second surface (S) of the insulating substrate 20 are the same surface. A resin insulating layer (outermost resin insulating layer) (50F) is formed on the first surface (F) of the core substrate 30. A conductor layer (outermost conductor layer) (58F) is formed on the resin insulating layer (50F). The conductor layer (58F) and the first conductor layer (34F) or the through-hole conductors 36 are connected to each other by via conductors (60F) that penetrate the resin insulating layer (50F). An upper side build-up layer (55F) is formed by the resin insulating layer (50F), the conductor layer (58F) and the via conductors (60F). In the embodiment, the upper side build-up layer is a single layer.

A resin insulating layer (outermost resin insulating layer) (50S) is formed on the second surface (S) of the core substrate 30. A conductor layer (outermost conductor layer) (58S) is formed on the resin insulating layer (50S). The conductor layer (58S) and the second conductor layer (34S) or the through-hole conductors are connected to each other by via conductors (60S) that penetrate the resin insulating layer (50S). A lower side build-up layer (55S) is formed by the resin insulating layer (50S), the conductor layer (58S) and the via conductors (60S). In the embodiment, the lower side build-up layer is a single layer.

An upper side solder resist layer (70F) is formed on the upper build-up layer (55F), and a lower side solder resist layer (70S) is formed on the lower build-up layer (55S). The solder resist layer (70F) has openings (71F) for exposing pads (75F). The metal posts 90 protruding from the openings (71F) are formed on the pads (75F). The solder resist layer (70S) has openings (71S) exposing BGA pads (71SP). A surface treatment film may be formed on the metal posts 90 and the BGA pads (71SP). Examples of the surface treatment film include Ni/Au, Ni/Pd/Au, Pd/Au, Ni/Sn and OSP.

### Manufacturing Method

A method for manufacturing the printed wiring board 10 according to the embodiment illustrated in FIG. 3D is illustrated in FIGS. 1A-1E, 2A-2E and 3A-3D.

The core substrate 30 illustrated in FIG. 1A is prepared. The core substrate 30 includes: the insulating substrate 20 having the first surface (F) and the second surface (S) on an opposite side with respect to the first surface (F); the first conductor layer (34F) formed on the first surface (F) of the insulating substrate 20; and the second conductor layer (34S) formed on the second surface of the insulating substrate 20. The core substrate 30 further includes the through holes 28 for the through-hole conductors formed in the insulating substrate 20. The through holes 28 are filled with a plating film to form the through-hole conductors 36.

The resin insulating layer (50F) is formed on the first surface (F) of the core substrate 30, and the resin insulating layer (50S) is formed on the second surface (S) of the core substrate 30. The openings (51F) are formed in the resin insulating layer (50F), and the openings (51S) are formed in the resin insulating layer (50S) (FIG. 1B). An electroless plating layer 52 is formed by an electroless plating treatment on a surface and in the openings (51F) of the resin insulating layer (50F) and on a surface and in the openings (51S) of the resin insulating layer (50S) (FIG. 1C). The electroless plating layer 52 is formed of, for example, Cu. A plating resist pattern 54 is formed on the electroless plating layer 52 (FIG. 1D).

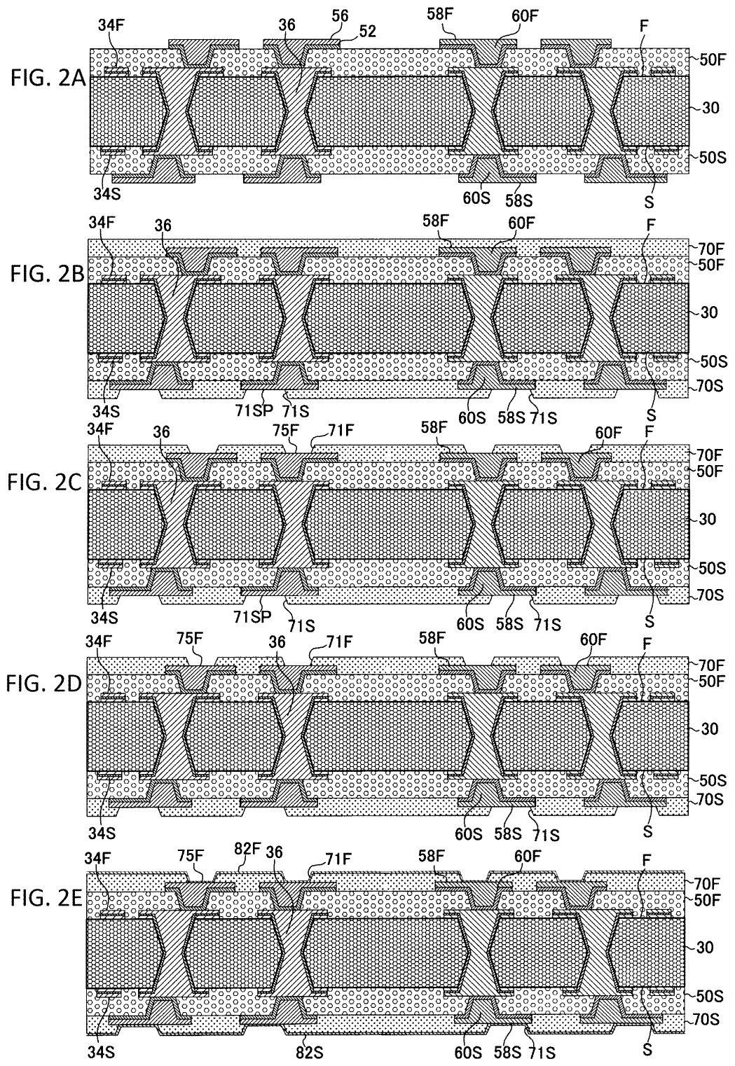

Using the electroless plating layer 52 as a seed layer, an electrolytic plating film 56 is formed by electrolytic plating on the electroless plating layer 52 exposed from the plating resist pattern 54. In this case, the via conductors (60F) are formed in the openings (51F), and the via conductors (60S) are formed in the openings (51S) (FIG. 1E). The electrolytic plating film 56 is formed of, for example, Cu. The plating resist pattern 54 is removed, the electroless plating layer 52 exposed from the electrolytic plating film 56 is removed, and the conductor layer (58F) and the conductor layer (58S) are formed (FIG. 2A). The upper side solder resist layer (70F) is formed on the resin insulating layer (50F) and the conductor layer (58F), and the lower side solder resist layer (70S) is formed on the resin insulating layer (505) and the conductor layer (58S). The lower side solder resist layer (70S) has the openings (71S) exposing the BGA pads (71SP) (FIG. 2B). The openings (71F) for exposing the pads (75F) are formed in the upper side solder resist layer (70F) using laser (FIG. 2C). Surfaces of the upper side solder resist layer (70F) and the lower side solder resist layer (70S) are irradiated with plasma, and the surfaces are treated to have an average roughness (Ra) of about 0.06 μm or more and 0.15 μm or less.

As a result, wettability of the surfaces is increased, and adhesion to an underfill material or the like is increased. A surface treatment film may be formed on the BGA pads (71SP). Examples of the surface treatment film include Ni/Au, Ni/Pd/Au, Pd/Au, Ni/Sn and OSP.

A palladium catalyst is formed on the surfaces of the upper side solder resist layer (70F) and the lower side solder resist layer (70S) by a palladium catalyst chemical treatment. An adsorption amount of the palladium catalyst is 3.0 mg/m² or more and 6.0 mg/m² or less (FIG. 2D). The adsorption amount of the palladium catalyst is adjusted by concentration, temperature, and immersion time of the palladium catalyst chemical solution.

The electroless plating layers (82F, 82S) each having a film thickness of 0.22 μm or more and 0.38 μm or less are respectively formed by an electroless plating treatment on the surface of the upper side solder resist layer (70F), side walls of the openings (71F), and the pads (75F), and on the surface of the lower side solder resist layer (70S), side walls of the openings (71S), and the BGA pads (71SP) (FIG. 2E). The palladium catalyst is applied to the surfaces of the upper side solder resist layer (70F) and the lower side solder resist layer (70S) at 3.0 mg/m² or more and 6.0 mg/m² or less, and nuclei of plating deposition are uniformly dispersed. Therefore, the electroless plating layers (82F, 82S) each having a uniform thickness and a film thickness of 0.22 μm or more and 0.38 μm or less are formed without occurrence of a non-deposition portion. The electroless plating layers (82F, 82S) are formed of, for example, Cu.

Since the film thickness of each of the electroless plating layers is 0.22 μm or more, the electroless plating layers can each be formed with a uniform film thickness without occurrence of a plating non-deposition portion. Since the film thickness of each of the electroless plating layers is as thin as 0.38 μm or less, it is thought that internal stresses in the plating coating films are reduced. Therefore, it is thought that, even when the electroless plating layers are heated by an annealing treatment, peeling or swelling of the plating coating films is unlikely to occur, and adhesion of the electroless plating layers to the surfaces of the solder resist layers is improved.

A plating resist (86F) having openings (86A) for metal post formation is formed on the electroless plating layer (82F). A plating resist (86S) protecting the BGA pads (71SP) is formed on the electroless plating layer (82S) (FIG. 3A). The metal posts 90 formed of the electrolytic plating film 84 is formed by electrolytic plating using the electroless plating layer (82F) as a seed layer (FIG. 3B). The electrolytic plating film 84 is formed of, for example, Cu. A protective film may be formed on the metal posts 90. Examples of the protective film include Ni/Au, Ni/Pd/Au, Pd/Au, Ni/Sn and OSP. The plating resists (86F, 86S) are peeled off (FIG. 3C). The electroless plating layer (82F) exposed from metal posts 90, and the electroless plating layer (82S) on the surface of the lower side solder resist layer (70S), the side walls of the openings (71S) and the BGA pads (71SP) are removed, and the printed wiring board 10 is completed (FIG. 3D).

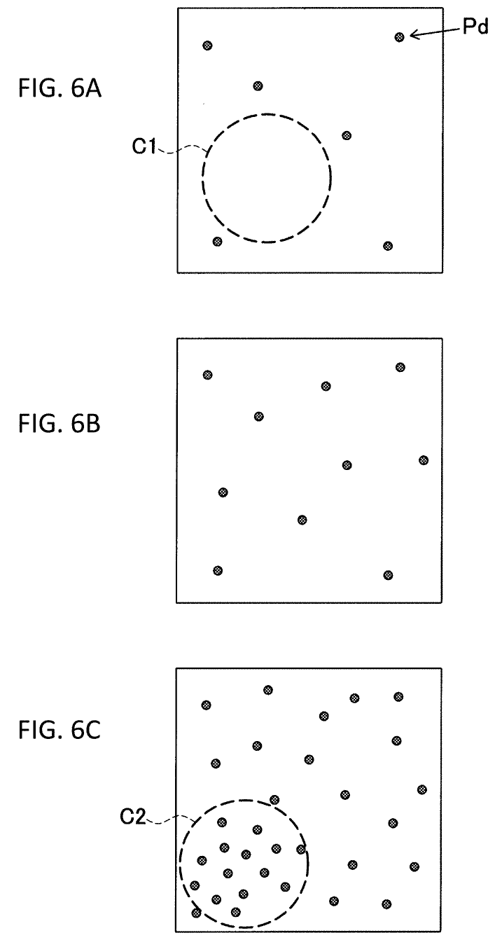

FIGS. 6A-6C are schematic diagrams of palladium catalyst application.

FIG. 6A illustrates a case where the palladium adsorption amount is small (the amount of the catalyst is less than 3.0 mg/m²). In a region indicated by a chain line circle (C1) in FIG. 6A, since intervals between particles of the palladium catalyst are large, a plating coating film cannot be formed and non-deposition occurs.

FIG. 6B illustrates a case where the palladium adsorption amount is appropriate (the amount of the catalyst is 3.0 mg/m² or more and 6.0 mg/m² or less). Since the palladium catalyst is uniformly dispersed, a uniform plating coating film having a small film thickness can be formed.

FIG. 6C illustrates a case where the palladium adsorption amount is excessive (the amount of the catalyst is more than 6.0 mg/m²). In a region indicated by a chain line circle (C2) in FIG. 8C, the palladium catalyst is concentrated. In the region indicated by the chain line circle (C2), plating deposition becomes excessive and the plating coating film is partially increased in thickness.

### Example 1

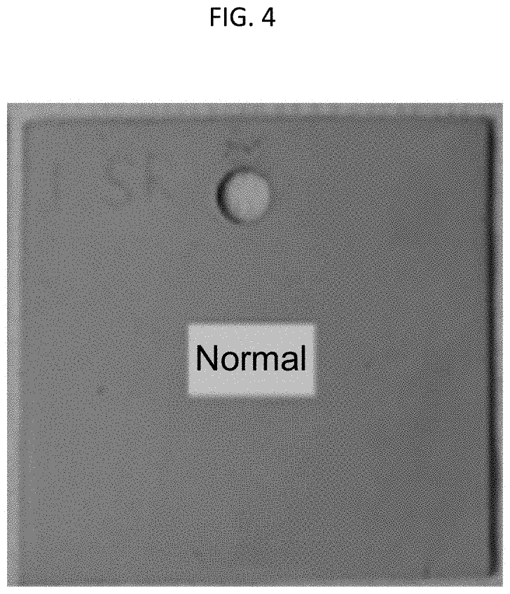

In the process of applying the palladium catalyst to the surfaces of the solder resist layers illustrated in FIG. 2C of the embodiment, in Example 1, the adsorption amount of the palladium catalyst is 4.8 mg/m². Then, in the process of forming the electroless plating layers on the surfaces of the solder resist layers illustrated in FIG. 2D of the embodiment, in Example 1, the electroless plating layers were formed to each have a thickness in a range of 0.232 μm-0.284 μm. FIG. 4 is a planar photograph of an electroless plating layer. The electroless plating layer was formed to have a thickness in a range of 0.232 μm-0.284 μm over the entire layer without occurrence of a non-deposition portion. In Example 1, it was possible to form the electroless plating layer having a substantially uniform film thickness (in a range of 0.232 μm-0.284 μm) without occurrence of a plating non-deposition portion.

### Comparative Example 1

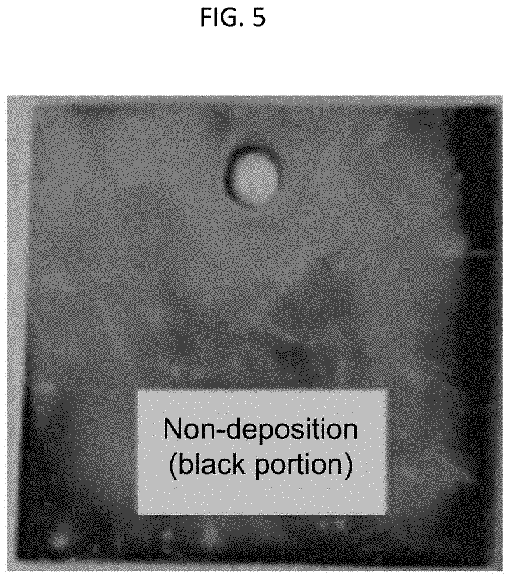

In the process of applying the palladium catalyst to the surfaces of the solder resist layers illustrated in FIG. 2C of the embodiment, in Comparative Example 1, the palladium catalyst is adsorbed at 4.8 mg/m². Then, in the process of forming the electroless plating layers on the surfaces of the solder resist layers illustrated in FIG. 2D of the embodiment, in Comparative Example 1, the electroless plating layers were formed to each have a thickness in a range of 0 μm-0.268 μm. FIG. 5 is a planar photograph of an electroless plating layer. A black portion in the photograph is where non-deposition of the electroless plating layer has occurred. In Comparative Example 1, non-deposition occurred in a portion of the electroless plating layer, and it was not possible to form an electroless plating layer having a uniform film thickness.

When a plating coating film is formed on a solder resist layer having a low surface roughness, an anchor effect due to a concave-convex shape of the surface is difficult to be obtained, and thus, adhesion of the plating coating film to the solder resist layer is weakened. In this case, when the film thickness of the plating coating film on the solder resist layer is too large, it is thought that a stress generated during a heat treatment increases and thereby, peeling or swelling of the plating coating film is likely to occur. It is thought that, in Japanese Patent No. 5579160, it is difficult to form an electroless plating film with an appropriate film thickness and excellent adhesion on a solder resist layer.

A method for manufacturing a printed wiring board according to an embodiment of the present invention includes: forming an outermost resin insulating layer; forming an outermost conductor layer on the outermost resin insulating layer; forming a solder resist layer on the outermost resin insulating layer and the outermost conductor layer; irradiating an exposed surface of the solder resist layer with plasma; forming a catalyst on the exposed surface; and forming an electroless plating layer on the exposed surface via the catalyst. The electroless plating layer has a film thickness of 0.22 μm or more and 0.38 μm or less.

In a printed wiring board according to an embodiment of the present invention, since the film thickness of the electroless plating layer is 0.22 μm or more, the electroless plating layer can be formed with a uniform film thickness without occurrence of a plating non-deposition portion. Since the film thickness of the electroless plating layer is 0.38 μm or less, it is thought that an internal stress in the plating coating film is reduced. Therefore, it is thought that peeling or swelling of the plating coating film is unlikely to occur and adhesion of the electroless plating layer to the surface of the solder resist layer is improved.

Obviously, numerous modifications and variations of the present invention are possible in light of the above teachings. It is therefore to be understood that within the scope of the appended claims, the invention may be practiced otherwise than as specifically described herein.

What is claimed is:

1. A method for manufacturing a printed wiring board, comprising:
forming an outermost conductor layer on an outermost resin insulating layer;
forming a solder resist layer on the outermost resin insulating layer such that the solder resist layer covers the outermost conductor layer formed on the outermost resin insulating layer;
irradiating plasma upon an exposed surface of the solder resist layer formed on the outermost conductor layer;
forming a catalyst on the exposed surface of the solder resist layer formed on the outermost conductor layer; and
forming an electroless plating layer on the exposed surface of the solder resist layer via the catalyst formed on the exposed surface of the solder resist layer such that the electroless plating layer has a film thickness in a range of 0.22 μm to 0.38 μm.

2. The method for manufacturing a printed wiring board according to claim 1, further comprising:
forming a plating resist on the electroless plating layer such that the plating resist has an opening exposing a portion of the electroless plating layer;
applying electrolytic plating using the electroless plating layer as a seed layer such that a metal post comprising electrolytic plating material is formed in the opening of the plating resist;
removing the plating resist from the electroless plating layer; and
removing the electrodeless plating layer exposed from the metal post,
wherein the forming of the solder resist layer comprises forming the solder resist layer on the outermost resin insulating layer such that the solder resist layer has an opening exposing a portion of the outermost conductor layer, the forming of the electroless plating layer comprises forming the electroless plating layer on the exposed surface of the solder resist layer via the catalyst and the portion of the outermost conductor layer, and the forming of the plating resist comprises forming the plating resist on the electroless plating layer such that the opening of the plating resist exposes the portion of the electroless plating layer formed in the opening of the solder resist layer.

3. The method for manufacturing a printed wiring board according to claim 1, wherein the forming of the catalyst comprises forming the catalyst on the exposed surface of the solder resist layer such that an amount of the catalyst is in a range of 3.0 mg/m² to 6.0 mg/m².

4. The method for manufacturing a printed wiring board according to claim 1, wherein the catalyst is Pd.

5. The method for manufacturing a printed wiring board according to claim 1, wherein the irradiating of the plasma comprises irradiating of the plasma on the exposed surface of the solder resist layer before the forming of the catalyst.

6. The method for manufacturing a printed wiring board according to claim 2, wherein the forming of the catalyst comprises forming the catalyst on the exposed surface of the solder resist layer such that an amount of the catalyst is in a range of 3.0 mg/m² to 6.0 mg/m².

7. The method for manufacturing a printed wiring board according to claim 2, wherein the catalyst is Pd.

8. The method for manufacturing a printed wiring board according to claim 2, wherein the irradiating of the plasma comprises irradiating of the plasma on the exposed surface of the solder resist layer before the forming of the catalyst.

9. The method for manufacturing a printed wiring board according to claim 3, wherein the catalyst is Pd.

10. The method for manufacturing a printed wiring board according to claim 3, wherein the irradiating of the plasma comprises irradiating of the plasma on the exposed surface of the solder resist layer before the forming of the catalyst.

11. The method for manufacturing a printed wiring board according to claim 4, wherein the irradiating of the plasma comprises irradiating of the plasma on the exposed surface of the solder resist layer before the forming of the catalyst.

12. The method for manufacturing a printed wiring board according to claim 6, wherein the catalyst is Pd.

13. The method for manufacturing a printed wiring board according to claim 6, wherein the irradiating of the plasma comprises irradiating of the plasma on the exposed surface of the solder resist layer before the forming of the catalyst.

14. The method for manufacturing a printed wiring board according to claim 12, wherein the irradiating of the plasma comprises irradiating of the plasma on the exposed surface of the solder resist layer before the forming of the catalyst.

15. The method for manufacturing a printed wiring board according to claim 1, wherein the irradiating of the plasma comprises irradiating the plasma upon the exposed surface of the solder resist layer such that the exposed surface of the solder resist is treated to have an average roughness Ra in a range of about 0.06 μm to 0.15 μm.

16. The method for manufacturing a printed wiring board according to claim 1, wherein the forming of the catalyst comprises applying a palladium catalyst chemical treatment on the exposed surface of the solder resist layer.

17. The method for manufacturing a printed wiring board according to claim 2, wherein the irradiating of the plasma comprises irradiating the plasma upon the exposed surface of the solder resist layer such that the exposed surface of the solder resist is treated to have an average roughness Ra in a range of about 0.06 μm to 0.15 μm.

18. The method for manufacturing a printed wiring board according to claim 2, wherein the forming of the catalyst comprises applying a palladium catalyst chemical treatment on the exposed surface of the solder resist layer.

19. The method for manufacturing a printed wiring board according to claim 3, wherein the irradiating of the plasma comprises irradiating the plasma upon the exposed surface of the solder resist layer such that the exposed surface of the solder resist is treated to have an average roughness Ra in a range of about 0.06 μm to 0.15 μm.

20. The method for manufacturing a printed wiring board according to claim 1, wherein the forming of the solder resist layer comprises forming the solder resist layer on the outermost resin insulating layer such that the solder resist layer has an opening exposing a portion of the outermost conductor layer, and the forming of the electroless plating layer comprises forming the electroless plating layer on the exposed surface of the solder resist layer via the catalyst and the portion of the outermost conductor layer.
